(19) United States
(12) Patent Application Publication
(10) Pub. No.: US 2026/0179677 A1
(43) Pub. Date: Jun. 25, 2026

(54) VOLATILE MEMORY DEVICE WITH GROUPED MEMORY CELLS

(71) Applicant: SAMSUNG ELECTRONICS CO., LTD., Suwon-si (KR)

(72) Inventors: Ho Seok LEE, Suwon-si (KR); Kyu-Chang Kang, Suwon-si (KR); Young Seok Park, Suwon-si (KR); Chul Kwon Park, Suwon-si (KR)

(73) Assignee: SAMSUNG ELECTRONICS CO., LTD., Suwon-si (KR)

(21) Appl. No.: 19/406,071

(22) Filed: Dec. 2, 2025

(30) Foreign Application Priority Data
Dec. 20, 2024 (KR) 10-2024-0192497

(51) Int. Cl. G11C 11/408; G11C 5/06; G11C 11/406

(52) U.S. Cl. CPC G11C 11/4085; G11C 5/063; G11C 11/406

(57) ABSTRACT

A volatile memory device includes: a first chip comprising a sub word line driving (SWD) circuit that applies a word line enable voltage to activate one or more selected memory cells; and a second chip bonded to the first chip so that a surface of the first chip and a surface of the second chip are in contact with each other, the second chip comprising a first memory cell, a second memory cell, a first conductive line connecting the first memory cell to the SWD circuit, and a second conductive line connecting the second memory cell to the SWD circuit, in which the first memory cell receives a first word line enable voltage, and in which the second memory cell receives a second word line enable voltage.

### CROSS-REFERENCE TO RELATED APPLICATION

This application claims priority from Korean Patent Application No. 10-2024-0192497 filed on Dec. 20, 2024, in the Korean Intellectual Property Office and all the benefits accruing therefrom under 35 U.S.C. 119, the contents of which in its entirety are herein incorporated by reference.

### BACKGROUND

### Technical Field

The present disclosure relates to a volatile memory device with grouped memory cells.

### Description of the Related Art

Recently, with multi-function and high performance of information communication devices, there is a demand for large capacity and high integration of memory devices. Attempts to form memory cells in various structures, such as vertically stacking memory cells beyond a planar structure, for large capacity and high integration have been made. In particular, in a three-dimensional structure in which memory cells are stacked in a vertical direction with respect to a substrate, as the number of memory cells is increased, the design of a conductive line for connecting a plurality of memory cells with a logic also becomes complicated. For example, in a design process of a memory device, it is required to consider a difference in RC components according to a difference in length of conductive lines having various lengths. Accordingly, even though a same voltage may be applied to the memory cells, a magnitude of a voltage received by a transistor of a lower memory cell may be lower than that of a voltage received by a transistor of an upper memory cell.

### BRIEF SUMMARY

An object of the present disclosure is to provide a volatile memory device with improved power consumption and improved reliability of stored data by compensating for a difference in characteristics between memory cells due to a difference in RC components of conductive lines having various lengths.

The objects of the present disclosure are not limited to those mentioned above and additional objects of the present disclosure, which are not mentioned herein, will be clearly understood by those skilled in the art from the following description of the present disclosure.

According to an aspect of the disclosure, a volatile memory device including: a first chip comprising a sub word line driving (SWD) circuit that applies a word line enable voltage to activate one or more selected memory cells; and a second chip bonded to the first chip so that a surface of the first chip and a surface of the second chip are in contact with each other, the second chip comprising (i) a first memory cell, (ii) a second memory cell, (iii) a first conductive line connecting the first memory cell to the SWD circuit, and (iv) a second conductive line connecting the second memory cell to the SWD circuit, in which the first memory cell receives a first word line enable voltage from the SWD circuit through the first conductive line, in which the second memory cell receives a second word line enable voltage from the SWD circuit through the second conductive line, the second word line enable voltage having a voltage level higher than the first word line enable voltage, and in which a length of the second conductive line is longer than a length of the first conductive line.

According to an aspect of the disclosure, a volatile memory device includes: a first chip comprising a sub word line driving (SWD) circuit that applies a word line enable voltage to activate one or more selected memory cells; and a second chip bonded to the first chip so that a surface of the first chip and a surface of the second chip are in contact with each other, the second chip comprising a substrate and a plurality of memory cells stacked in a first direction perpendicular to the substrate, in which a first memory cell of the plurality of memory cells receives a first word line enable voltage from the SWD circuit, and in which a second memory cell has a stack level different from a stack level of the first memory cell among the plurality of memory cells, in which the second memory cell receives a second word line enable voltage from the SWD circuit, and in which the second word line enable voltage has a voltage level different from a voltage level of the first word line enable voltage.

According to an aspect of the disclosure, a volatile memory device including: a first chip comprising (i) a refresh controller that refreshes one or more selected memory cells in accordance with a preset period, and (ii) a sub word line driving (SWD) circuit that applies, under control of the refresh controller, a word line enable voltage for refreshing the one or more selected memory cells; and a second chip bonded to the first chip so that a surface of the first chip and a surface of the second chip are in contact with each other, the second chip comprising (i) a first memory cell, (ii) a second memory cell, (iii) a first conductive line connecting the first memory cell to the SWD circuit, and (iv) a second conductive line connecting the second memory cell to the SWD circuit, in which the refresh controller refreshes, by controlling the SWD circuit, the first memory cell in a first period, in which the refresh controller refreshes, by controlling the SWD circuit, the second memory cell in a second period shorter than the first period, and in which a length of the second conductive line is longer than a length of the first conductive line.

Details of the other embodiments are included in the detailed description and drawings.

### BRIEF DESCRIPTION OF THE DRAWINGS

FIG. 1 is a block diagram illustrating a memory system according to one or more embodiments.

FIG. 2 is a block diagram illustrating the memory device of FIG. 1 according to one or more embodiments.

FIG. 3 is a view illustrating a memory device of a three-dimensional structure according to one or more embodiments.

FIG. 4 is a plan view illustrating a first chip according to one or more embodiments.

FIG. 5 is a circuit diagram illustrating a second chip according to one or more embodiments.

FIG. 6 is a plan view illustrating a second chip according to one or more embodiments.

FIG. 7 is a perspective view illustrating a second chip according to one or more embodiments.

FIG. 8 is a circuit diagram illustrating a grouping method according to a height difference between memory cells according to one or more embodiments.

FIG. 9 is a circuit diagram illustrating a grouping method according to a height difference between memory cells according to one or more embodiments.

FIG. 10 is a view illustrating a method of providing a different word line enable voltage to each memory cell group according to one or more embodiments.

FIG. 11 is a view illustrating a method of performing a refresh operation by varying a period for each memory cell group according to one or more embodiments.

FIG. 12 is a plan view illustrating a second chip according to one or more embodiments.

FIG. 13 is a perspective view illustrating a second chip according to one or more embodiments.

FIG. 14 is a plan view illustrating a grouping method according to an overlap relation between regions according to one or more embodiments.

### DETAILED DESCRIPTION OF THE DISCLOSURE

Hereinafter, the embodiments according to the technical spirits of the present disclosure will be described with reference to the accompanying drawings.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

As used herein, the term “connected” or “connecting” is intended to encompass both a direct connection between two elements and an indirect connection in which one or more intermediate elements, devices, or structures may be interposed. Unless specifically stated otherwise, a recitation that one element is “connected to” another element includes both cases in which the elements are in direct physical or electrical contact and cases in which the elements are operatively coupled through one or more intervening components.

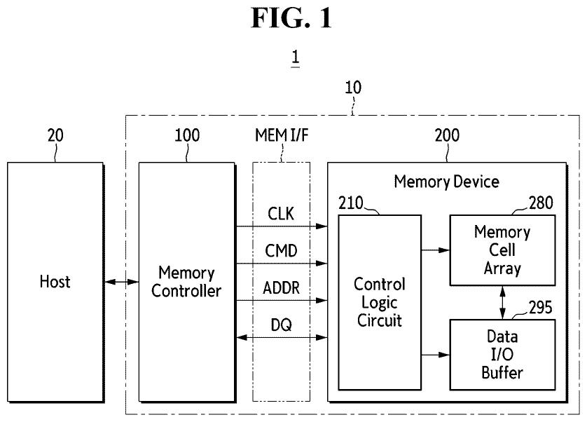

FIG. 1 is a block diagram illustrating a memory system according to one or more embodiments.

Referring to FIG. 1, a memory system 1 may include a host 20 and a memory storage device 10. The memory storage device 10 may include a memory device 200 and a memory controller 1000.

The memory controller 1000 may control an overall operation of the memory device 200. For example, the memory controller 100 may control data exchange between the external host 20 and the memory device 200. For example, the memory controller 100 may control the memory device 200 in accordance with a request of the host 20, thereby writing or reading data.

The memory controller 100 and the memory device 200 may perform communication with each other through a memory interface MEM I/F. In one or more examples, the memory controller 100 and the external host 20 may perform communication with each other through a host interface. That is, the memory controller 100 may relay signals between the memory device 200 and the host 20. The memory controller 100 may control the operation of the memory device 200 by applying a command CMD for controlling the memory device 200. In this case, the memory device 200 may include dynamic memory cells. For example, the memory device 200 may include a Dynamic Random Access Memory (DRAM), Double Data Rate 4 (DDR4), a Synchronous DRAM (SDRAM), a Low Power DDR4 (LPDDR4) SDRAM, or LPDDR5 SDRAM, but the embodiments according to the technical spirits of the present disclosure are not limited thereto. The memory device 200 may include a nonvolatile memory device. However, in the present embodiments, the memory device 200 will be described as a volatile memory device.

The memory controller 100 may transmit a clock signal CLK, a command CMD, an address ADDR signal, etc. to the memory device 200. The memory controller 100 may provide data DQ to the memory device 200, and may receive the data DQ from the memory device 200. The memory device 200 may include a memory cell array 280 for storing the data DQ, a control logic circuit 210 and a data input/output buffer 295.

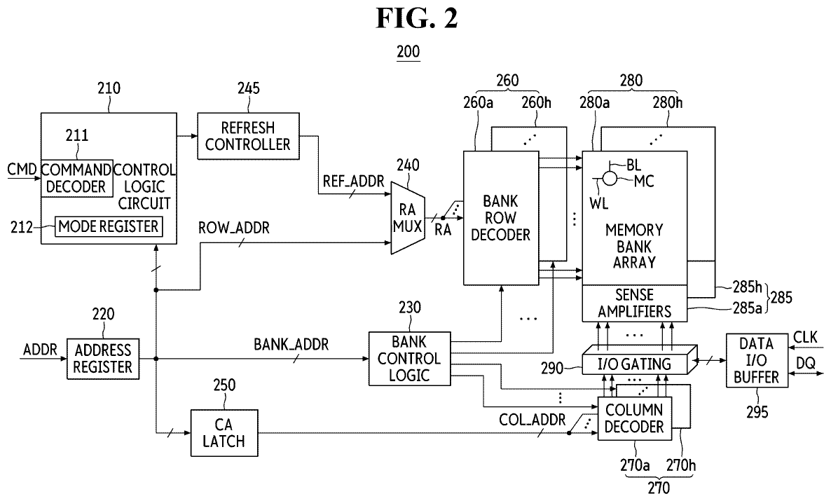

FIG. 2 is a block diagram illustrating the memory device of FIG. 1 according to one or more embodiments.

Referring to FIG. 2, the memory device 200 may include, for example, a control logic circuit 210, an address register 220, a bank control logic circuit 230, a row address multiplexer 240, a refresh controller 245, a column address latch 250, a row decoder 260, a column decoder 270, a memory cell array 280, a sense amplifier 285, an input/output gating circuit 290, and a data input/output buffer 295.

The memory cell array 280 may include a plurality of memory bank arrays 280a to 280h. Although FIG. 2 shows that the memory cell array 280 includes eight memory bank arrays 280a to 280h, the present disclosure is not limited thereto.

Each of the plurality of memory bank arrays 280a to 280h may include a plurality of word lines WL, a plurality of bit lines BL, and a plurality of memory cells MC formed at a point where the word lines WL and the bit lines BL cross each other.

The control logic circuit 210 may control the operation of the memory device 200. For example, the control logic circuit 210 may generate control signals so that the memory device 200 performs a write operation or a read operation. The control logic circuit 210 may include a command decoder 211 for decoding a command CMD received from the memory controller 100 and a mode register 212 for setting an operation mode of the memory device 200.

The row address multiplexer 240 may include a plurality of bank row decoders 260a to 260h connected to the plurality of memory bank arrays 280a to 280h, respectively. The column decoder 270 may include a plurality of column decoders 270a to 270h connected to a plurality of memory bank arrays 280a to 280h, respectively. The sense amplifier 285 may include a plurality of sense amplifiers 285a to 285h connected to the plurality of memory bank arrays 280a to 280h, respectively.

The address register 220 may receive an address ADDR, which includes a bank address BANK_ADDR, a row address ROW_ADDR and a column address COL_ADDR, from the memory controller (100 of FIG. 1). The address register 220 may provide the received bank address BANK_ADDR to the bank control logic circuit 230, provide the received row address ROW_ADDR to the row address multiplexer 240 and provide the received column address COL_ADDR to the column address latch 250.

The bank control logic circuit 230 may generate bank control signals in response to the bank address BANK_ADDR. In response to the bank control signals, the bank row decoder, which corresponds to the bank address BANK_ADDR, among the plurality of bank row decoders 260a to 260h may be activated, and the column decoder, which corresponds to the bank address BANK_ADDR, among the plurality of column decoders 270a to 270h may be activated.

The refresh controller 245 may perform a refresh operation in response to a refresh command received from the control logic circuit 210. For example, the refresh controller 245 may perform a refresh operation for a memory unit selected in accordance with a set refresh period TREF. In one or more examples, the refresh controller 245 may output a refresh address REF_ADDR for refresh.

The row address multiplexer 240 may receive the row address ROW_ADDR from the address register 220, and may receive the refresh address REF_ADDR from the control logic circuit 210. The row address multiplexer 240 may selectively output the row address ROW_ADDR or the refresh address REF_ADDR as a row address RA. The row address RA output from the row address multiplexer 240 may be applied to each of the plurality of bank row decoders 260a to 260h.

The bank row decoder, which is activated by the bank control logic circuit 230, among the plurality of bank row decoders 260a to 260h may decode the row address RA output from the row address multiplexer 240 to activate a word line corresponding to the row address. For example, the activated bank row decoder may apply a word line driving voltage to the word line corresponding to the row address.

The column address latch 250 may receive the column address COL_ADDR from the address register 220, and may temporarily store the received column address COL_ADDR. The column address latch 250 may gradually increase the received column address COL_ADDR in a burst mode. The column address latch 250 may apply the temporarily stored column address COL_ADDR or the gradually increased column address COL_ADDR to each of the plurality of column decoders 270a to 270h.

The bank column decoder, which is activated by the bank control logic circuit 230, among the plurality of column decoders 270a to 270h may activate the sense amplifier corresponding to the bank address BANK_ADDR and the column address COL_ADDR through the corresponding input/output gating circuit 290.

The input/output gating circuit 290 may include an input data mask logic, read data latches for storing data output from the plurality of memory bank arrays 280a to 280h, and write drivers for writing data in the plurality of memory bank arrays 280a to 280h, along with circuits for gating input/output data.

The data DQ to be read from one bank array among the plurality of memory bank arrays 280a to 280h may be sensed by a sense amplifier (e.g., one of 285a to 285h) corresponding to the one bank array and stored in the read data latches. The data DQ stored in the read data latches may be provided to the memory controller 100 through the data input/output buffer 295.

The data DQ to be written in one of the plurality of memory bank arrays 280a to 280h may be provided to the input/output gating circuit 290, and the input/output gating circuit 290 may write the data in the one bank array through the write drivers.

The memory cells MC may be, for example, DRAM memory cells. Each of the memory cells MC may be connected to one word line WL and one bit line BL. The memory cell MC may store charges through a cell capacitor. Since a leakage current occurs in the memory cell MC due to a structure of the memory cell MC, data stored in the cell capacitor may be destroyed.

Therefore, the memory device 200 may perform a refresh operation of recharging data in the memory cell MC to prevent the data stored in the memory cell MC from being changed by a leakage current.

The memory device 200 may have a three-dimensional structure. For example, the memory device 200 may have a chip to chip (C2C) structure. The C2C structure may refer to a chip including a cell region is manufactured, a chip including a peripheral circuit region is manufactured, and then the two chips are stacked to be connected to each other. For example, the cell region may include the memory cell array 280. The peripheral circuit region may include the control logic circuit 210, the address register 220, the bank control logic circuit 230, the row address multiplexer 240, the column address latch 250, the row decoder 260, the column decoder 270, the sense amplifier 285, the input/output gating circuit 290, the data input/output buffer 295, etc., but the present disclosure is not limited thereto. Each of the cell region and the peripheral circuit region may further include different components, or some components thereof may be omitted.

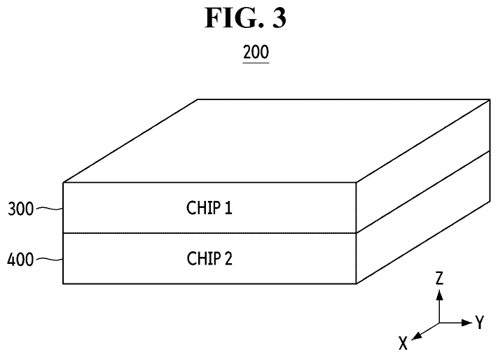

FIG. 3 is a view illustrating a memory device of a three-dimensional structure.

Referring to FIG. 3, the memory device 200 may be manufactured by connecting bonding pads formed on a lowermost metal layer of a first chip 300 to a bonding pad formed on an uppermost metal layer of a second chip 400 by bonding to be in contact with each other. For example, when the bonding pads are formed of copper (Cu), the bonding method may be a Cu—Cu bonding method, and the bonding pads may be also formed of aluminum or tungsten. In Cu—Cu bonding, two copper surfaces may be joined directly without the need for solder or other bonding agents. The Cu—Cu bonding may be performed using thermal compression bonding or surface activation bonding. The first chip 300 may include a cell region, and the second chip 400 may include a peripheral circuit region. However, according to the embodiment of the present disclosure, the first chip 300 may include a peripheral circuit region, and the second chip 400 may include a cell region, but the present disclosure is not limited thereto. Hereinafter, for convenience of description, the description will be based on that the first chip 300 includes a peripheral circuit region and the second chip 400 includes a cell region. As understood by one of ordinary skill in the art, the embodiments are not limited to Cu—Cu bonding. For example, the first chip 300 and the second chip 400 may be bonded using a metal-metal hybrid bonding process that may include forming a bond between two metals by fusing embedded metal pads in a bond interface. This bonding technique advantageously enables heterogeneous integration to connect two components of two different functions and sizes.

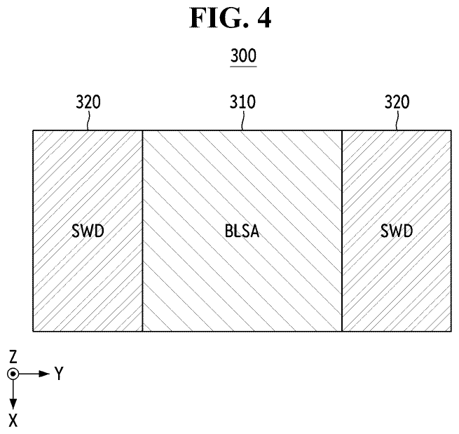

FIG. 4 is a plan view illustrating a first chip according to one or more embodiments.

Referring to FIG. 4, a bit-line sense amplifier (BLSA) circuit 310 and a sub word-line driver (SWD) circuit 320 may be arranged in a partial region on the first chip 300.

The BLSA circuit 310 may correspond to the sense amplifier 285 described in FIG. 2. The BLSA circuit 310 may sense data stored in a memory cell array, amplify a voltage corresponding to the sensed data and output the amplified data to an external device in response to a request from the external device.

The SWD circuit 320 may include a plurality of sub word line drivers SWD capable of driving a plurality of sub word lines. The SWD circuit 320 may activate a sub word line selected in response to a word line driving signal and a word line enable signal. In the present disclosure, the term ‘sub word line’ may be used interchangeably with the term ‘word line’.

The SWD circuit 320 may apply a word line enable voltage VPP higher than a power voltage VDD to the selected word line in accordance with the word line driving signal (e.g., PXID) and the word line enable signal (e.g., NWEI). The SWD circuit 320 may apply the word line enable voltage VPP to the selected word line to activate the corresponding word line (or a memory cell connected to the corresponding word line).

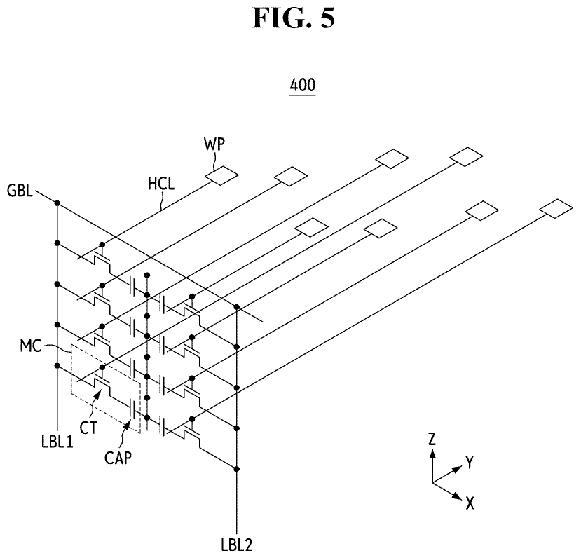

FIG. 5 is a circuit diagram illustrating a second chip according to one or more embodiments.

Referring to FIG. 5, the second chip may include a plurality of memory cells MC. Each memory cell may include a cell transistor TR and a data storage element CAP. Although eight memory cells are shown in FIG. 5, this is for convenience of description, and the number of memory cells is not limited to eight. As understood by one of ordinary skill in the art, the number of memory cells may be more than eight or less than eight. The cell transistor TR and the data storage element CAP may be connected in series. The bit lines may be conductive patterns (e.g., metallic conductive lines) extended in a vertical direction Z. The bit lines may be spaced apart from each other along a first horizontal direction Y and a second horizontal direction X. The first horizontal direction Y and the second horizontal direction X may cross each other. The first horizontal direction Y, the second horizontal direction X and the vertical direction Z may cross one another. Hereinafter, a lower portion, an upper portion, a lower surface and an upper surface are defined based on the vertical direction Z.

The bit lines may include a first local bit line LBL1, a second local bit line LBL2, and a global bit line GBL. Although two local bit lines and one global bit line are shown in FIG. 5, this is for convenience of description, and the number of bit lines is not limited as above. The local bit lines LBL1 and LBL2 may be spaced apart from each other along the second horizontal direction X.

Some of the bit lines may be connected to each other by the global bit line GBL. For example, the local bit lines LBL1 and LBL2, which are spaced apart from each other along the second horizontal direction X, may be connected to each other by the global bit line GBL.

Horizontal conductive lines HCL may be conductive patterns (e.g., metallic conductive lines) extended from each memory cell MC in the first horizontal direction Y. The horizontal conductive lines HCL may be portions of word lines connecting a logic circuit (e.g., the SWD circuit 320) with each memory cell MC. A word line pad WP connecting a vertical conductive line extended along the vertical direction Z from an upper surface of the second chip with the horizontal conductive line HCL may be formed at an end of each horizontal conductive line HCL. To connect the vertical conductive lines extended along the vertical direction Z from the upper surface of the second chip 400 with the memory cells stacked vertically on the substrate, the horizontal conductive lines HCL may have a stepped structure. However, the structure suggested above is an example of the three-dimensional memory cell structure, and each of the memory cells and the conductive lines may be formed in a different structure.

The horizontal conductive line HCL may be connected to a gate of the cell transistor TR of each memory cell MC, a first source/drain of the cell transistor TR may be connected to the data storage element CAP, and a second source/drain of the cell transistor TR may be connected to the bit line. The data storage element CAP may be a capacitor or a variable resistor. Hereinafter, for convenience of description, it is assumed that the data storage element CAP is a capacitor.

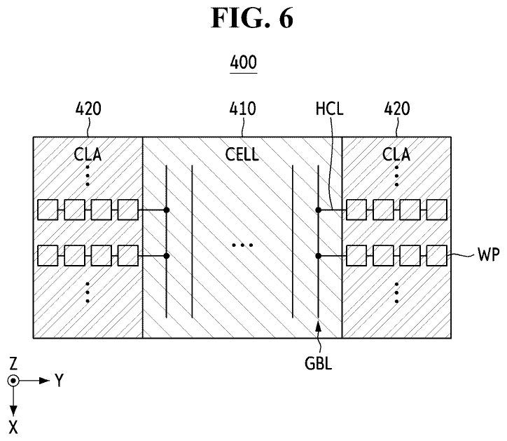

FIG. 6 is a plan view illustrating a second chip according to one or more embodiments.

Referring to FIG. 6, a memory cell region CELL 410 and a conductive line region CLA 420 may be arranged in a partial region on the second chip 400. When upper surfaces of the first chip 300 and the second chip 400 are bonded to each other in contact with each other, the memory cell region 410 may at least partially overlap the BLSA circuit 310 on the first chip 300 in the vertical direction Z in FIG. 5. In one or more examples, when the surfaces of the first chip 300 and the second chip 400 are bonded to each other, the conductive line region 420 may at least partially overlap the SWD circuit 320 on the first chip 300 in the vertical direction Z. Regions shown in the same shade in the first chip 300 of FIG. 4 and the second chip 400 of FIG. 6 indicate an overlap relation with each other. A plurality of memory cells and bit lines, which are vertically stacked on the substrate in the second chip 400, may be arranged in the memory cell region 410 when the second chip 400 is viewed in the vertical direction Z, and word line pads WP formed at an end of the horizontal conductive line extended from each memory cell in the first horizontal direction Y may be arranged in the conductive line region 420 when the second chip 400 is viewed in the vertical direction Z. That is, a plurality of memory cells and bit lines, which are vertically stacked on the substrate in the second chip 400, may overlap the memory cell region 410 in the vertical direction Z, and word line pads WP formed at an end of the horizontal conductive line extended from each memory cell in the first horizontal direction Y may overlap the conductive line region 420 in the vertical direction Z.

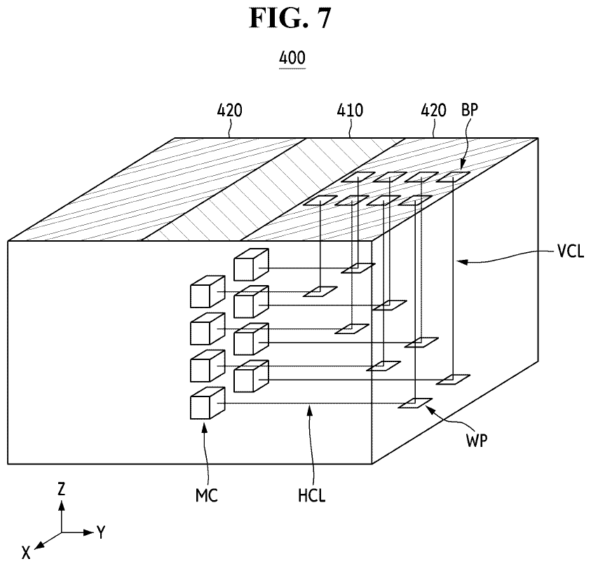

FIG. 7 is a perspective view illustrating a second chip according to one or more embodiments.

Referring to FIG. 7, a plurality of bonding pads BP may be arranged on an upper portion of the second chip 400. For convenience of description, it is assumed that the first chip 300 and the second chip 400 are connected to each other through the bonding pads, but the present disclosure is not limited thereto. When the first chip 300 and the second chip 400 are bonded to each other in contact with each other, the bonding pads BP of the second chip 400 may be in contact with the bonding pads of the first chip 300 to connect the second chip 400 with the first chip 300. Although the bonding pads BP are shown as being arranged on the conductive line region 420 of the second chip 400, this is only exemplary, and the bonding pads BP may be arranged anywhere on the upper portion of the second chip 400. The vertical conductive lines VCL may be extended from the bonding pads BP of the second chip 400 in the vertical direction Z and thus may be connected to the word line pads WP. In FIG. 7, the vertical conductive lines VCL are shown as being extended in the vertical direction Z, however, this configuration is for convenience of description, and each vertical conductive line VCL may partially include a portion extended in the first horizontal direction Y or the second horizontal direction X for design reasons.

The plurality of memory cells MC of the second chip 400 may be connected to the bonding pads BP through the corresponding horizontal conductive line HCL and the corresponding vertical conductive line VCL. A length of the corresponding conductive line connecting one memory cell MC with the corresponding bonding pad BP may be defined as a sum of lengths of the corresponding horizontal conductive line HCL and the corresponding vertical conductive line VCL. In this case, the length of the horizontal conductive line HCL corresponding to one memory cell MC may be defined as a length of a line extended from the cell transistor to the word line pad WP. In one or more examples, the length of the vertical conductive line VCL corresponding to one memory cell MC may be defined as a length of a line extended from the word line pad WP to the bonding pad BP.

As the memory cell becomes highly integrated, a length of a conductive line connecting the memory cell with a logic tends to become longer, and a thickness of the conductive line tends to become thinner. As the length of the conductive line becomes longer and the thickness of the conductive line becomes thinner, a size of RC component generated on the conductive line is also increased. For example, when the same word line enable voltage is applied to two memory cells having different lengths of conductive lines, magnitudes of voltages received by gates of the two memory cells may be different due to the RC component.

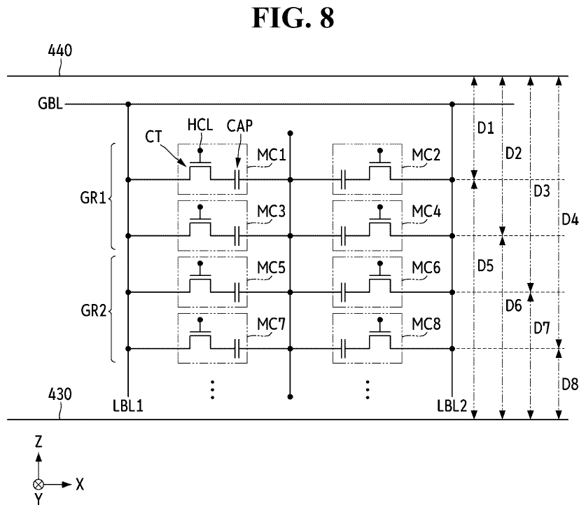

FIG. 8 is a circuit diagram illustrating a grouping method according to a height difference between memory cells according to one or more embodiments.

Referring to FIG. 8, a plurality of memory cells MC1 to MC8 may be stacked on a substrate 430 of the second chip 400 in the vertical direction Z. Accordingly, stack levels of the plurality of memory cells MC1 to MC8 may be different. For example, the first memory cell MC1 and the second memory cell MC2 may have the same stack level or may have a different stack level from the other memory cells. In addition, the third memory cell MC3 and the fourth memory cell MC4 may have the same stack level or may have a different stack level from the other memory cells. A height of each memory cell in the vertical direction Z may be different depending on the stack levels. For example, a distance D1 between the first and second memory cells MC1 and MC2 and an upper portion 440 of the second chip 400 may be the shortest of all the distances, a distance D2 between the third and fourth memory cells MC3 and MC4 and the upper portion 440 of the second chip 400 may be the second shortest of all the distances, a distance D3 between the fifth and sixth memory cells MC5 and MC6 and the upper portion 440 of the second chip 400 may be the third shortest of all the distances, and a distance D4 between the seventh and eighth memory cells MC7 and MC8 and the upper portion 440 of the second chip 400 may be the longest all the distances.

A distance D5 between the first and second memory cells MC1 and MC2 and the substrate 430 may be the longest of all the distances, a distance D6 between the third and fourth memory cells MC3 and MC4 and the substrate 430 of the second chip 400 may be the second longest of all the distances, a distance D7 between the fifth and sixth memory cells MC5 and MC6 and the substrate 430 of the second chip 400 may be the third longest of all the distances, and a distance D8 between the seventh and eighth memory cells MC7 and MC8 and the substrate 430 of the second chip 400 may be the shortest of all the distances.

According to some embodiments, the plurality of memory cells MC1 to MC8 may be grouped depending on the stack levels. For example, the first and second memory cells MC1 and MC2 having the shortest distance D1 to the upper portion 440 of the second chip 400, and the third and fourth memory cells MC3 and MC4 having the second shortest distance D2 to the upper portion 440 of the second chip 400 may be grouped into a first group GR1. In addition, the seventh and eighth memory cells MC7 and MC8 having the longest distance D4 to the upper portion 440 of the second chip 400 and the fifth and sixth memory cells MC5 and MC6 having the second longest distance D3 to the upper portion 440 of the second chip 400 may be grouped into a second group GR2.

Since a memory cell may be farther from an upper portion in which the bonding pad is arranged in the second chip 400, a length of the vertical conductive line corresponding to the corresponding memory cell may be longer. In one or more examples, since the horizontal conductive lines have a stepped structure, as a distance from an upper portion in which the bonding pad is arranged in the second chip 400 is farther, the length of the horizontal conductive line corresponding to the corresponding memory cell may be longer. Therefore, as a memory cell is farther from an upper portion in which the bonding pad is arranged in the second chip 400, the length of the conductive line corresponding to the corresponding memory cell may be longer. That is, the length of the conductive line of the memory cells belonging to the second group GR2 may be longer than the length of the conductive line of the memory cells belonging to the first group GR1.

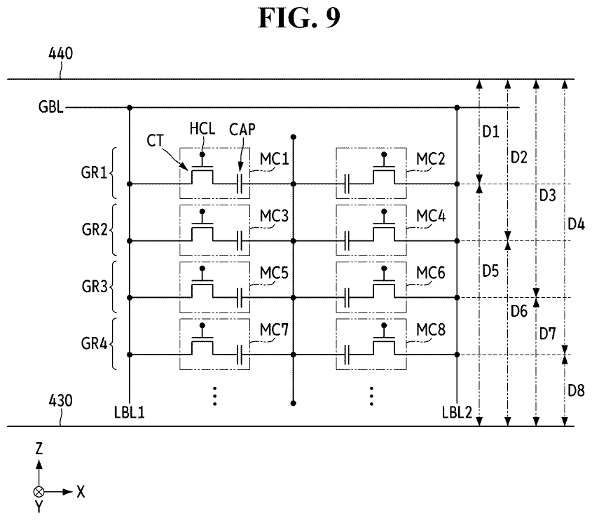

FIG. 9 is a circuit diagram illustrating a grouping method according to a height difference between memory cells according to one or more embodiments.

Referring to FIG. 9, unlike FIG. 8, the plurality of memory cells MC1 to MC8 may be grouped into three or more groups depending on stack levels. For example, the first and second memory cells MC1 and MC2 having the shortest distance D1 to the upper portion 440 of the second chip 400 may be grouped into a first group GR1. In one or more examples, the third and fourth memory cells MC3 and MC4 having the second shortest distance D2 to the upper portion 440 of the second chip 400 may be grouped into a second group GR2. In one or more examples, the fifth and sixth memory cells MC5 and MC6 having the second longest distance D3 to the upper portion 440 of the second chip 400 may be grouped into a third group GR3. In one or more examples, the seventh and eighth memory cells MC7 and MC8 having the longest distance D4 to the upper portion 440 of the second chip 400 may be grouped into a fourth group GR4.

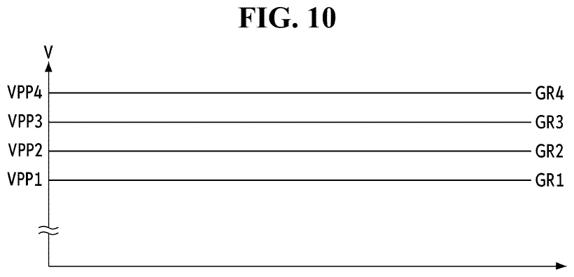

FIG. 10 is a view illustrating a method of providing a different word line enable voltage to each memory cell group according to one or more embodiments.

Referring to FIG. 10, an SWD circuit (e.g., the SWD circuit 320 of FIG. 4) may apply a group-specific different voltage to memory cells belonging to different groups. For example, the SWD circuit may apply a word line enable voltage VPP having a group-specific different magnitude to the selected word line in accordance with the word line driving signal and the word line enable signal.

Assume, for example, that the plurality of memory cells MC1 to MC8 are grouped into four groups GR1 to GR4 depending on the stack levels. As a result, memory cells belonging to a group relatively far from the upper portion of the second chip in which the bonding pad is arranged may have a relatively larger RC component of the conductive line than memory cells belonging to a group relatively close to the upper portion of the second chip.

According to some embodiments, the SWD circuit may apply a first word line enable voltage VPP1 to the memory cells belonging to the first group GR1, apply a second word line enable voltage VPP2 to the memory cells belonging to the second group GR2, apply a third word line enable voltage VPP3 to the memory cells belonging to the third group GR3 and apply a fourth word line enable voltage VPP4 to the memory cells belonging to the fourth group GR4. In this case, when the fourth word line enable voltage VPP4 has a voltage level equivalent to that of the VPP, for example, the third word line enable voltage VPP3 may have a voltage level of about VPP-50 mV, the second word line enable voltage VPP2 may have a voltage level of about VPP-100 mV, and the first word line enable voltage VPP1 may have a voltage level of about VPP-150 mV. The voltage level of each of the above-described word line enable voltages VPP1 to VPP4 is exemplary, but is not limited thereto.

Even though the SWD circuit applies the same word line enable voltage to each word line, a magnitude of a voltage transferred to the gate of each memory cell may vary depending on the stack levels. For example, when the level of the word line enable voltage applied to activate the memory cells belonging to the fourth group GR4 is VPP, the memory cells belonging to the first group GR1 may be activated even though the word line enable voltage has a voltage level lower than that of the VPP. Therefore, according to some embodiments, the word line enable voltage having a different voltage level may be applied to each group, so that a memory device with improved power consumption may be provided.

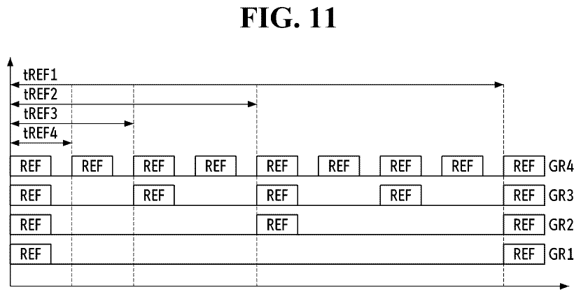

FIG. 11 is a view illustrating a method of performing a refresh operation by varying a period for each memory cell group according to one or more embodiments.

Referring to FIG. 11, a refresh controller (e.g., the refresh controller 245 of FIG. 2) may perform a refresh operation for the memory cells belonging to different groups by varying a period for each memory cell group. In this case, the refresh controller may perform a refresh operation, by controlling the SWD circuit, for the memory cells belonging to different groups, and one period may mean the time required to refresh a specific memory cell again after refreshing the specific memory cell.

It is assumed, for example, that the plurality of memory cells MC1 to MC8 are grouped into four groups GR1 to GR4 depending on the stack levels. As a result, memory cells belonging to a group relatively far from the upper portion of the second chip in which the bonding pad is arranged may have a relatively larger RC component of the conductive line than memory cells belonging to a group relatively close to the upper portion of the second chip.

According to some embodiments, the refresh controller may refresh the memory cells belonging to the first group GR1 in a first period tREF1 by controlling the SWD circuit, may refresh the memory cells belonging to the second group GR2 in a second period tREF2 by controlling the SWD circuit, may refresh the memory cells belonging to the third group GR3 in a third period tREF3 by controlling the SWD circuit, and may refresh the memory cells belonging to the fourth group GR4 in a fourth period tREF4 by controlling the SWD circuit. In this case, the second period tREF2 may be half of the first period tREF1, the third period tREF3 may be half of the second period tREF2, and the fourth period tREF4 may be half of the third period tREF3. Each of the above-described periods is merely an example, and the embodiments are not limited to these configuration.

Due to the difference in RC components due to the difference in length of the conductive lines, data storage elements (e.g., capacitors, etc.) of memory cells belonging to a group relatively far from the upper portion of the second chip in which the bonding pad is arranged may be more vulnerable to current leakage than data storage elements of memory cells belonging to a group relatively close to the upper portion of the second chip. Therefore, according to some embodiments, the refresh period of the memory cells belonging to a group relatively far from the upper portion of the second chip in which the bonding pad is arranged may be set to be shorter than that of the memory cells belonging to a group relatively close to the upper portion of the second chip, so that a memory device with improved reliability of stored data may be provided.

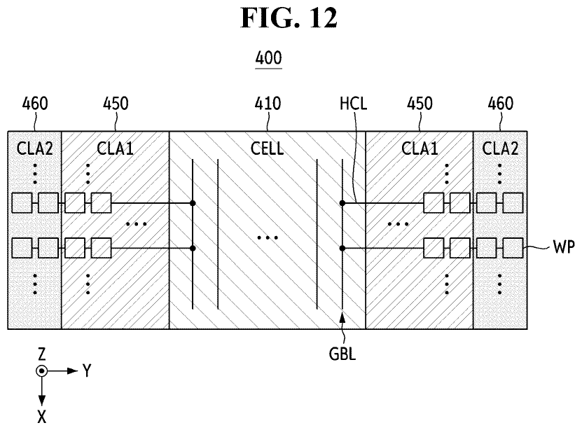

FIG. 12 is a plan view illustrating a second chip according to one or more embodiments.

A detailed description of redundant portions of those described in FIG. 6 will be omitted in FIG. 12. Referring to FIG. 12, a memory cell region 410 and a conductive line region may be arranged in a partial region of the second chip 400. The conductive line region may be divided into a first conductive line region 450 and a second conductive line region 460. When the upper surfaces of the first chip 300 and the second chip 400 are bonded to each other in contact with each other, the memory cell region 410 may at least partially overlap the BLSA circuit 310 on the first chip 300 in the vertical direction Z. In one or more examples, when the upper surfaces of the first chip 300 and the second chip 400 are bonded to each other in contact with each other, the conductive line region may at least partially overlap the SWD circuit 320 on the first chip 300 in the vertical direction Z.

In this case, a region of the conductive line region, which overlaps the SWD circuit 320 in the vertical direction Z, may be divided into the first conductive line region 450, and a region of the conductive line region, which does not overlap the SWD circuit 320 in the vertical direction Z, may be divided into the second conductive line region 460.

A plurality of memory cells and bit lines, which are vertically stacked on a substrate in the second chip 400, may be arranged in the memory cell region 410 when the second chip 400 is viewed in the vertical direction Z, and word line pads WP formed at an end of a horizontal conductive line extended from each memory cell in the first horizontal direction Y may be arranged in the first conductive line region 450 and the second conductive line region 460 when the second chip 400 is viewed in the vertical direction Z.

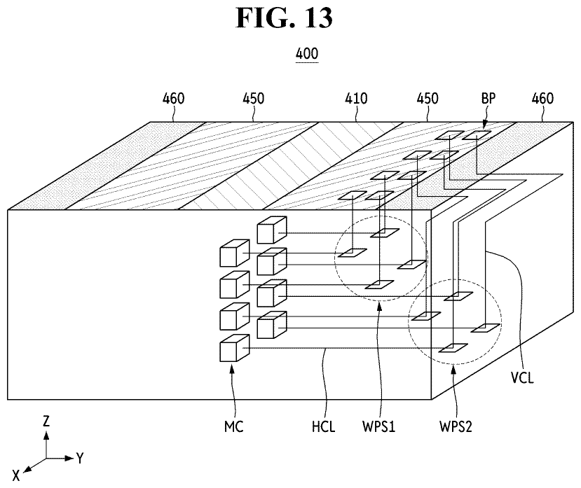

FIG. 13 is a perspective view illustrating a second chip according to one or more embodiments.

A detailed description of redundant portions of those described in FIG. 7 will be omitted in FIG. 13. Referring to FIG. 13, a plurality of bonding pads BP may be arranged on an upper portion of the second chip 400. When the first chip 300 and the second chip 400 are bonded to each other in contact with each other, the bonding pads BP of the second chip 400 may connect the second chip 400 to the first chip 300 in contact with the bonding pads of the first chip 300. Although the bonding pads BP are shown as being arranged on the first conductive line region 450 of the second chip 400, this is an example, and the bonding pads BP may be arranged anywhere on the upper portion of the second chip 400. The vertical conductive lines VCL may be extended from the bonding pads BP of the second chip 400 in the vertical direction Z and thus connected to the word line pads WP. Although the vertical conductive lines VCL are shown as being accurately extended in the vertical direction Z, this is for convenience of description, and for design reasons, each vertical conductive line VCL may partially include a portion extended in the first horizontal direction Y or the second horizontal direction X. The plurality of memory cells MC of the second chip 400 may be connected to the bonding pads BP through the corresponding horizontal conductive line HCL and the corresponding vertical conductive line VCL, respectively.

With a large capacity and high integration of a memory device, there is a demand to reduce an area occupied by various logic circuits arranged in the first chip 300. Accordingly, an area occupied by the SWD circuit in the first chip 300 may be also limited. As a result, some of the word line pads may not overlap the SWD circuit in the vertical direction Z. For example, a first word line pad set WPS1 may be arranged in the first conductive line region 420 when the second chip 400 is viewed in the vertical direction Z, and the first word line pad set WPS1 may overlap the SWD circuit in the vertical direction Z. A second word line pad set WPS2 may be arranged in the second conductive line region 420 when the second chip 400 is viewed in the vertical direction Z, and the second word line pad set WPS2 may not overlap the SWD circuit in the vertical direction Z.

Since the word line pads included in the second word line pad set WPS2 do not overlap the SWD circuit in the vertical direction Z, the vertical conductive lines connected to the corresponding word line pads need to be partially extended relatively long in the first horizontal direction Y or the second horizontal direction X. On the other hand, since the word line pads included in the first word line pad set WPS1 overlap the SWD circuit in the vertical direction Z, the vertical conductive lines connected to the corresponding word line pads may be partially extended relatively short in the first horizontal direction Y or the second horizontal direction X, or may be only extended in the vertical direction Z. Therefore, lengths of the conductive lines connected to the word line pads included in the second word line pad set WPS2 may be relatively longer than lengths of the conductive lines connected to the word line pads included in the first word line pad set WPS1.

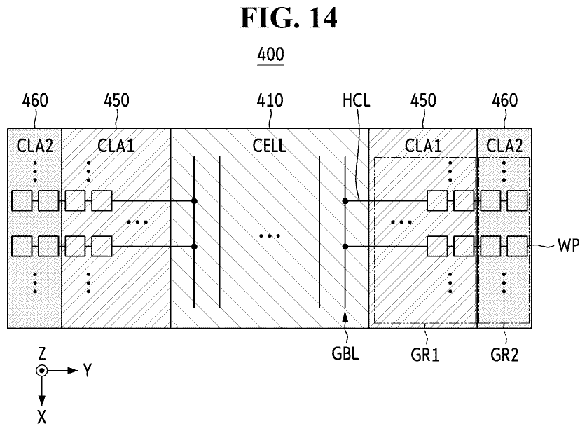

FIG. 14 is a plan view illustrating a grouping method according to an overlap relation between regions according to one or more embodiments.

A detailed description of redundant portions of those described in FIGS. 6 and 12 will be omitted in FIG. 14. Referring to FIG. 14, word line pads arranged in the first conductive line region 450 and memory cells connected to the corresponding word line pads may be grouped into a first group GR1. Word line pads arranged in the second conductive line region 460 and memory cells connected to the corresponding word line pads may be grouped into a second group GR2.

As described above, the first conductive line region 450 may be a region that overlaps the SWD circuit in the vertical direction Z, and the second conductive line region 460 may be a region that does not overlap the SWD circuit in the vertical direction Z. Therefore, the word line pads included in the first word line pad set WPS1 of FIG. 13 may overlap the first conductive line region 450 in the vertical direction Z. On the other hand, the word line pads included in the second word line pad set WPS2 of FIG. 13 may overlap the second conductive line region 460 in the vertical direction Z. For the reasons described above, lengths of the conductive lines of the memory cells belonging to the second group GR2 may be longer than lengths of the conductive lines of the memory cells belonging to the first group GR1.

The description will be made with reference to FIG. 14 together with FIG. 9. According to some embodiments, the SWD circuit may apply a first word line enable voltage VPP1 to the memory cells belonging to the first group GR1 and apply a second word line enable voltage VPP2 to the memory cells belonging to the second group GR2. A voltage level of the first word line enable voltage VPP1 may be lower than that of the second word line enable voltage VPP2.

Even though the SWD circuit applies the same word line enable voltage to each word line, a magnitude of a voltage transferred to a gate of each memory cell may be different due to a length difference according to a structure of the conductive line. For example, it is assumed that a level of a word line enable voltage applied to activate the memory cells belonging to the second group GR2 is VPP. In this case, the memory cells belonging to the first group GR1 may be sufficiently activated even though the word line enable voltage has a voltage level lower than that of the VPP. Therefore, according to some embodiments, the word line enable voltage having a different voltage level may be applied to each group, so that a memory device with improved power consumption may be provided.

The description will be made with reference to FIG. 14 together with FIG. 10. According to some embodiments, the refresh controller may refresh the memory cells belonging to the first group GR1 in the first period tREF1 and refresh the memory cells belonging to the second group GR2 in the second period tREF2. In this case, the second period tREF2 may be half of the first period tREF1. Each of the above-described periods is an example and is not limited thereto.

The data storage elements (e.g., capacitors) of the memory cells belonging to the second group GR2 may be more vulnerable to current leakage than the data storage elements of the memory cells belonging to the first group GR1 due to the difference in RC components according to the difference in length of the conductive lines. Accordingly, the refresh period of the memory cells connected to the word line pads, which overlap the second conductive line region 460 in the vertical direction Z, may be set to be shorter than the refresh period of the memory cells connected to the word line pads, which overlap the first conductive line region 450 in the vertical direction Z, whereby a memory device with improved reliability of stored data may be provided.

Although some embodiments of the present disclosure have been described above with reference to the accompanying diagrams, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

1. A volatile memory device comprising:
a first chip comprising a sub word line driving (SWD) circuit that applies a word line enable voltage to activate one or more selected memory cells; and
a second chip bonded to the first chip so that a surface of the first chip and a surface of the second chip are in contact with each other, the second chip comprising:
a first memory cell;
a second memory cell;
a first conductive line connecting the first memory cell to the SWD circuit; and
a second conductive line connecting the second memory cell to the SWD circuit,
wherein the first memory cell receives a first word line enable voltage from the SWD circuit through the first conductive line,
wherein the second memory cell receives a second word line enable voltage from the SWD circuit through the second conductive line, the second word line enable voltage having a voltage level higher than the first word line enable voltage, and
wherein a length of the second conductive line is longer than a length of the first conductive line.

2. The volatile memory device of claim 1, wherein a distance from the surface of the second chip to the first memory cell in a first direction perpendicular to the second chip is shorter than a distance from the surface of the second chip to the second memory cell in the first direction.

3. The volatile memory device of claim 2, wherein the second chip further comprises:
a first memory cell group comprising a plurality of memory cells including the first memory cell; and
a second memory cell group comprising a plurality of memory cells including the second memory cell, and
wherein each distance from the surface of the second chip to the plurality of memory cells of the first memory cell group in the first direction is shorter than each distance from the surface of the second chip to the plurality of memory cells of the second memory cell group in the first direction.

4. The volatile memory device of claim 1, wherein the second chip further comprises a substrate,
wherein the first memory cell and the second memory cell are stacked on the substrate in a first direction perpendicular to the substrate, and a height of the first memory cell on the substrate in the first direction is higher than a height of the second memory cell on the substrate in the first direction.

5. The volatile memory device of claim 1, wherein the second chip further comprises:
a first conductive line region that overlaps the SWD circuit in a first direction perpendicular to the second chip; and
a second conductive line region that does not overlap the SWD circuit in the first direction,
wherein the first conductive line comprises:
a first horizontal conductive line extended from a first cell transistor in a second direction crossing the first direction; and
a first word line pad at an end of the first horizontal conductive line,
wherein the second conductive line comprises:
a second horizontal conductive line extended from a second cell transistor in the second direction; and
a second word line pad at an end of the second horizontal conductive line,
wherein the first word line pad overlaps the first conductive line region in the first direction, and
wherein the second word line pad overlaps the second conductive line region in the first direction.

6. The volatile memory device of claim 5, wherein the second chip further comprises:
a first memory cell group comprising one or more memory cells including the first memory cell;
a second memory cell group comprising one or more memory cells including the second memory cell;
a first conductive line group comprising the first conductive line and connecting the one or more memory cells of the first memory cell group to the SWD circuit; and
a second conductive line group including the second conductive line and connecting the one or more memory cells of the second memory cell group to the SWD circuit,
wherein each of conductive lines of the first conductive line group comprises a word line pad at an end of a horizontal conductive line extended from the one or more memory cells of the first memory cell group in the second direction, and overlapping the first conductive line region in the first direction, and
wherein each of conductive lines of the second conductive line group comprises a word line pad at an end of a horizontal conductive line extended from the one or more memory cells of the second memory cell group in the second direction, and overlapping the second conductive line region in the first direction.

7. The volatile memory device of claim 1, wherein the second chip further comprises:
a first memory cell group comprising a plurality of memory cells including the first memory cell;
a second memory cell group comprising a plurality of memory cells including the second memory cell;
a first conductive line group including a plurality of conductive lines including the first conductive line and connecting the plurality of memory cells of the first memory cell group to the SWD circuit; and
a second conductive line group including a plurality of conductive lines including the second conductive line and connecting the plurality of memory cells of the second memory cell group to the SWD circuit,
wherein the plurality of memory cells of the first memory cell group receive the first word line enable voltage,
wherein the plurality of memory cells of the second memory cell group receive the second word line enable voltage, and
wherein each length of the plurality of conductive lines of the first conductive line group is shorter than each length of the plurality of conductive lines of the second conductive line group.

8. The volatile memory device of claim 1, wherein the second chip further comprises: a third memory cell and a third conductive line connecting the third memory cell to the SWD circuit,
wherein the third memory cell receives a third word line enable voltage from the SWD circuit through the third conductive line, the third word line enable voltage having a voltage level higher than a voltage level of the second word line enable voltage, and
wherein a length of the third conductive line is longer than a length of the second conductive line.

9. A volatile memory device comprising:
a first chip comprising a sub word line driving (SWD) circuit that applies a word line enable voltage to activate one or more selected memory cells; and
a second chip bonded to the first chip so that a surface of the first chip and a surface of the second chip are in contact with each other, the second chip comprising:
a substrate; and
a plurality of memory cells stacked in a first direction perpendicular to the substrate,
wherein a first memory cell of the plurality of memory cells receives a first word line enable voltage from the SWD circuit, and
wherein a second memory cell has a stack level different from a stack level of the first memory cell among the plurality of memory cells,
wherein the second memory cell receives a second word line enable voltage from the SWD circuit, and
wherein the second word line enable voltage has a voltage level different from a voltage level of the first word line enable voltage.

10. The volatile memory device of claim 9, wherein a height of the first memory cell on the substrate in the first direction is higher than a height of the second memory cell on the substrate in the first direction, and
wherein a voltage level of the second word line enable voltage is higher than a voltage level of the first word line enable voltage.

11. The volatile memory device of claim 9, wherein a distance from the surface of the second chip to the first memory cell in the first direction is shorter than a distance from the surface of the second chip to the second memory cell in the first direction, and
wherein a voltage level of the second word line enable voltage is higher than a voltage level of the first word line enable voltage.

12. The volatile memory device of claim 9, wherein a first memory cell group including one or more memory cells having a same stack level as a stack level of the first memory cell among the plurality of memory cells receives the first word line enable voltage from the SWD circuit, and
wherein a second memory cell group including one or more memory cells having a same stack level as a stack level of the second memory cell among the plurality of memory cells receives the second word line enable voltage from the SWD circuit.

13. The volatile memory device of claim 9, wherein a third memory cell having a stack level different from a stack level of the first memory cell and a stack level of the second memory cell among the plurality of memory cells receives a third word line enable voltage from the SWD circuit, and
wherein the third word line enable voltage has a voltage level different from a voltage level of the first word line enable voltage and the second word line enable voltage.

14. The volatile memory device of claim 13, wherein a first memory cell group including one or more memory cells having a same stack level as a stack level of the first memory cell among the plurality of memory cells receives the first word line enable voltage from the SWD circuit,
wherein a second memory cell group comprising one or more memory cells having a same stack level as the stack level of the second memory cell among the plurality of memory cells receives the second word line enable voltage from the SWD circuit, and
wherein a third memory cell group including one or more memory cells having a same stack level as the stack level of the third memory cell among the plurality of memory cells receives the third word line enable voltage from the SWD circuit.

15. A volatile memory device comprising:
a first chip comprising:
a refresh controller that refreshes one or more selected memory cells in accordance with a preset period; and
a sub word line driving (SWD) circuit that applies, under control of the refresh controller, a word line enable voltage for refreshing the one or more selected memory cells; and
a second chip bonded to the first chip so that a surface of the first chip and a surface of the second chip are in contact with each other, the second chip comprising:
a first memory cell;
a second memory cell;
a first conductive line connecting the first memory cell to the SWD circuit; and
a second conductive line connecting the second memory cell to the SWD circuit,
wherein the refresh controller refreshes, by controlling the SWD circuit, the first memory cell in a first period,
wherein the refresh controller refreshes, by controlling the SWD circuit, the second memory cell in a second period shorter than the first period, and
wherein a length of the second conductive line is longer than a length of the first conductive line.

16. The volatile memory device of claim 15, wherein a distance from the surface of the second chip to the first memory cell in a first direction perpendicular to the second chip is shorter than a distance from the surface of the second chip to the second memory cell in the first direction.

17. The volatile memory device of claim 16, wherein the second chip further comprises:
a first memory cell group comprising a plurality of memory cells including the first memory cell; and
a second memory cell group comprising a plurality of memory cells including the second memory cell, and
wherein each distance from the surface of the second chip to the plurality of memory cells of the first memory cell group in the first direction is shorter than each distance from the surface of the second chip to the plurality of memory cells of the second memory cell group in the first direction.

18. The volatile memory device of claim 15, wherein the second chip further comprises a substrate,
wherein the first memory cell and the second memory cell are stacked on the substrate in a first direction perpendicular to the substrate, and
wherein a height of the first memory cell on the substrate in the first direction is higher than a height of the second memory cell on the substrate in the first direction.

19. The volatile memory device of claim 15, wherein the second chip further comprises:
a first conductive line region that overlaps the SWD circuit in a first direction passing through the second chip; and
a second conductive line region that does not overlap the SWD circuit in the first direction,
wherein the first conductive line comprises:
a first horizontal conductive line extended from a first cell transistor in a second direction crossing the first direction; and
a first word line pad at an end of the first horizontal conductive line,
wherein the second conductive line comprises:
a second horizontal conductive line extended from a second cell transistor in the second direction; and
a second word line pad at an end of the second horizontal conductive line,
wherein the first word line pad overlaps the first conductive line region in the first direction, and
wherein the second word line pad overlaps the second conductive line region in the first direction.

20. The volatile memory device of claim 19, wherein the second chip further comprises:
a first memory cell group comprising one or more memory cells including the first memory cell;
a second memory cell group comprising one or more memory cells including the second memory cell;
a first conductive line group including the first conductive line and connecting the one or more memory cells of the first memory cell group to the SWD circuit, and
a second conductive line group including the second conductive line and connecting the one or more memory cells of the second memory cell group to the SWD circuit,
wherein each of conductive lines of the first conductive line group comprises a word line pad at an end of a horizontal conductive line extended from the one or more memory cells of the first memory cell group in the second direction, and overlapping the first conductive line region in the first direction, and
wherein each of conductive lines of the second conductive line group comprises a word line pad at an end of a horizontal conductive line extended from the one or more memory cells of the second memory cell group in the second direction, and overlapping the second conductive line region in the first direction.

21. (canceled)

22. (canceled)
